(19) United States
(12) Patent Application Publication
(10) Pub. No.: US 2014/0345670 A1
(43) Pub. Date: Nov. 27, 2014

(54) Passively Tracking Partially Concentrating Photovoltaic Solar Panel

(71) Applicant: Luigi Fornari, Arlington, TX (US)

(72) Inventor: Luigi Fornari, Arlington, TX (US)

(21) Appl. No.: 13/899,652

(22) Filed: May 22, 2013

(51) Int. Cl. H01L 31/052; F24J 2/04

(52) U.S. Cl. CPC H01L 31/0524; F24J 2/0483
USPC 136/246; 126/663

(57) ABSTRACT

The invention relates to passively tracking, partially concentrating solar panels that feature the ability to perpetually self-concentrate impinging light on a portion of the underlying photovoltaic material during varying times of the day and throughout the year. Such solar panels feature higher conversion efficiencies and higher output when compared to equivalent sized conventional solar panels and do not require an active tracking system to adjust for yearly difference in the sun's elevation above the horizon.

### CROSS-REFERENCE TO RELATED APPLICATIONS

The present application takes benefit of U.S. Provisional App. 61/649,934 filed May 22, 2012 and incorporates it in its entirety by reference. The present application incorporates prior U.S. patent application Ser. No. 13/047,768 (Fresnel Lens Array With Novel Lens Element Profile) in its entirety by reference.

### FIELD OF THE INVENTION

The present invention relates to solar panels generally, and to solar panels that feature the ability to passively self-concentrate impinging light on a fixed portion of the underlying photovoltaic (PV) material during varying times of the day particularly, to yield a solar panel that features higher conversion efficiency and incrementally higher output when compared to an equivalent sized conventional solar panel constructed in the same manner and of the same PV material. On an “equivalent power” basis, i.e. when comparing a conventional solar panel and an improved solar panel constructed in accordance with the teachings of the preferred embodiment of the present invention, the improved panel can be constructed at far lower cost and obviates the need for an active tracking system.

### BACKGROUND OF THE INVENTION

Increasing the output per unit area of PV-based solar panels is of vital importance if the goal of reducing man's reliance on consumable carbon-based fuels to generate electricity is to ever be realized. Indeed, in some parts of the world the only electricity available is generated from comparatively small, highly inefficient diesel-powered generators thus leading to the paradox that people living in the poorest locales pay some of the highest prices for electricity. Lowering electricity prices and the resulting benefits flowing therefrom (e.g. light, refrigeration, and access to computer technology) for these individuals is a recognized human need.

Harnessing the power of the sun, and in particular improving the conversion efficiency of photovoltaic (PV) solar collectors, is thus an important societal goal. Thus far, efforts to improve the conversion efficiency of PV solar collectors have fallen into two broad areas: 1) “Endogenous” improvements in the nature of the PV material that comprises the assembly; and, 2) “Exogenous” improvements that deal broadly with methods of causing more sunlight to fall onto the PV material as the Earth daily rotates on its axis and as it yearly rotates around the sun.

In the “endogenous” area, the evolution of PV material has proceeded slowly—from costly single crystal silicon cells, to cheaper polycrystalline cells, through modern thin film cells with multiple layers of different materials stacked one on top of the other to capture photons in multiple energy band gaps. While thin film cells promise the highest conversion ratios they are the most expensive to manufacture. At the present time, conversion efficiencies of approximately 20% at one sun are routinely achievable in monocrystalline and polycrystalline applications, with polycrystalline panels available at installed prices below $1.00 per watt generated.

In the “exogenous” area, efforts have evolved along two lines: 1) Tracking—i.e. mechanical devices that ensure that the panel is optimally positioned with respect to the sun; and, 2) Concentration—i.e. the use of lenses or mirrors to concentrate more light into a smaller area of PV material—thus taking advantage of the fact that within limits, PV materials are more efficient in terms of energy conversion when used in concentrated light. Tracking and concentration techniques are unsurprisingly somewhat costly and thus were of more importance in the past when the underlying PV material was a limiting factor in terms of installed cost. Today, however, with installed prices below $1.00 per watt, most small to medium-sized installations feature simple arrays of low-cost static, non-concentrating panels. Because of this, realizing a means of creating a statically mounted solar panel that incorporates a low cost intrinsic concentrating ability without the need for costly directional control systems would be of great utility.

### BRIEF DESCRIPTION OF THE DRAWINGS

FIG. 1 is a partially exploded view of a passively tracking, partially concentrating photovoltaic solar panel in which the ridges and grooves that form the profile of each linear cylindrical Fresnel lens comprising a monolithic array of linear cylindrical Fresnel lenses are aligned along the east-west axis and lie parallel to the longitudinal center lines of the strips of photovoltaic material.

FIG. 2a is an example of a partially exploded view of a passively tracking, partially concentrating photovoltaic solar panel in which the ridges and grooves that form the profile of each linear cylindrical Fresnel lens comprising a monolithic array of linear cylindrical Fresnel lenses are aligned along the east-west axis and lie parallel to the longitudinal center lines of the strips of photovoltaic material. This figure shows the resulting linear focal zone of concentrated light cast on the underlying photovoltaic material by the southernmost element of the monolithic array of linear cylindrical Fresnel lenses at local A.M.

FIG. 2b is an example of a partially exploded view of a passively tracking, partially concentrating photovoltaic solar panel in which the ridges and grooves that form the profile of each linear cylindrical Fresnel lens comprising a monolithic array of linear cylindrical Fresnel lenses are aligned along the east-west axis and lie parallel to the longitudinal center lines of the strips of photovoltaic material. This figure shows the resulting linear focal zone of concentrated light cast on the underlying photovoltaic material by the southernmost element of the monolithic array of linear cylindrical Fresnel lenses at local noon.

FIG. 2c is an example of a partially exploded view of a passively tracking, partially concentrating photovoltaic solar panel in which the ridges and grooves that form the profile of each linear cylindrical Fresnel lens comprising a monolithic array of linear cylindrical Fresnel lenses are aligned along the east-west axis and lie parallel to the longitudinal center lines of the strips of photovoltaic material. This figure shows the resulting linear focal zone of concentrated light cast on the underlying photovoltaic material by the southernmost element of the monolithic array of linear cylindrical Fresnel lenses at local P.M.

FIG. 3 is a partial section through the right end of a passively tracking partially concentrating photovoltaic solar panel in which the ridges and grooves that form the profile of the lens are aligned along the east-west axis and lie parallel to the strips of photovoltaic material.

FIG. 4 is a partial section through the right end of a passively tracking partially concentrating photovoltaic solar panel showing a first arrangement of the components.

FIG. 5 is a partial section through the right end of a passively tracking partially concentrating photovoltaic solar panel showing a second arrangement of the components.

FIG. 6 is a partial section through the right end of a passively tracking partially concentrating photovoltaic solar panel showing a third arrangement of the components.

### SUMMARY OF THE INVENTION

Fresnel lenses have been used with solar collectors and solar cells in various “concentration configurations” for many years. For example, U.S. application Ser. No. 12/036,825 discloses a Fresnel lens as the primary focusing element for concentrating solar radiation on a single multi-junction solar cell. This is a classic solar concentrator, capable of providing a very high solar flux focused on a unitary discrete cell. Numerous other concentrator applications have been constructed throughout the years. As the market for photovoltaic devices has matured, the most common photovoltaic devices deployed are conventional monocrystalline or polycrystalline silicon-based “sheet” panels wherein individual solar cells are connected together into strips and the resulting strips are placed side-by-side into a rectangular panel. The entire assembly is then encased in plastic and typically covered by a sheet of glass. These devices are intrinsically non-concentrating: i.e. the amount of solar flux impinging on the panel approximates 1 sun (1 kW/m²) depending on the time of day and the time of year. These flat panels are usually mounted statically with no means of tracking or otherwise controlling the position of the panel with respect to the position of the sun.

While there has been experimentation combining Fresnel lenses with the types of solar panels now widely available, these experiments have tended to deal with affixing one or more circular Fresnel lenses to standard solar panels. Unknown in the prior art are applications in which a planar cylindrical Fresnel lens is affixed to a flat solar panel. The main reason Fresnel lenses are infrequently used in photovoltaic applications, in general, is that they must be molded or machined from some kind of plastic material. As a result, these lenses are generally unsuitable when exposed to the elements. Obviously, these lenses may be overlaid by glass to increase their viability in exposed applications, but this decreases the optical transmittance of the resulting assembly and attenuates the light provided to the surface of the photovoltaic element by at least 8% (4% per surface of the glass overlay). While such an assembly may, in theory, be constructed, recent technical advances have made it possible to mold Fresnel lenses out of glass, providing at one stroke a lens that is both durable and features intrinsically high transmittance at visible and infrared wavelengths. Such a lens is disclosed in U.S. patent application Ser. No. 13/047,768 (Fresnel Lens Array With Novel Lens Element Profile). Such lenses are far more suitable for applications involving solar panels than their plastic counterparts. Thus, the goal of the present invention is to provide a monolithic array of planar cylindrical Fresnel lenses that are used as a covering element for linear strips of photovoltaic material and serve to increase the conversion efficiency and electrical output of the underlying linear strips of photovoltaic material thus providing a solar panel with greater output and far lower construction costs when compared to conventional solar panels.

In a first, preferred, embodiment, a monolithic array of linear cylindrical Fresnel lenses is mounted such that both the ridges and grooves that form the profile of the lenses and the underlying strips of photovoltaic material are aligned east to west such that the linear focal zone of concentrated light each lens generates falls longitudinally along the center longitudinal line of a strip of photovoltaic material and appears to remain motionless as the sun traces its daily path along the ecliptic. In a second embodiment, a monolithic array of linear cylindrical Fresnel lenses is mounted such that the ridges and grooves that form the profile of the lenses are aligned east to west and the strips of photovoltaic material are aligned north to south such that the linear focal zone of concentrated light each lens generates falls perpendicularly across a multiplicity of strips of photovoltaic material and appears to remain motionless as the sun traces its daily path along the ecliptic. In a third embodiment, a monolithic array of linear cylindrical Fresnel lenses is mounted such that both the ridges and grooves that form the profile of the lenses and the strips of photovoltaic material are aligned north to south such that the linear focal zone of concentrated light each lens generates falls longitudinally along a strip of photovoltaic material and appears to move from west to east, possibly transitioning to a neighboring strip, as the sun traces its daily path along the ecliptic. In a fourth embodiment, a monolithic array of linear cylindrical Fresnel lenses is mounted such that the ridges and grooves that form the profile of the lenses are aligned north to south and the strips of photovoltaic material are aligned east to west such that the linear focal zone of concentrated light each lens generates falls perpendicularly across a multiplicity of strips of photovoltaic material and moves from west to east as the sun traces its daily path along the ecliptic. In addition, it will be apparent that an infinite number of other configurations are possible in which a monolithic array of linear cylindrical Fresnel lenses is mounted such that the linear focal points of concentrated light they generate fall across one or more strips of photovoltaic material at some angle between a line parallel to the longitudinal center lines of the photovoltaic strips and a line laying at right angles to the longitudinal center lines of the photovoltaic strips.

Generally, the first and second embodiments are favored because they have a much higher intrinsic solar acceptance angle—almost the full 180° arc that the sun traces daily across the sky. By contrast, the third and fourth embodiments are disfavored because the useful solar acceptance angle is low—perhaps only plus or minus 25° from the point at which the sun is highest on the ecliptic (i.e. local noon when the sun's rays are perpendicular to the plane of the solar panel). This is because linear cylindrical Fresnel lenses are incapable of providing a sharply focused line of concentrated sunlight at greater input angles (i.e. nearer each horizon). Of the first embodiment and the second embodiment, however, the first embodiment is preferred, because each strip of photovoltaic material may be placed at any necessary distance from its neighbor to ensure that each photovoltaic strip is evenly illuminated along its entire length. By this means, when used in areas with continuous, uninterrupted sunlight, photovoltaic strips may be omitted from the surface of the panel thus lowering manufacturing costs. Alternately, in areas with more diffuse sunlight, the entire surface of the panel may be covered with strips and the entire panel will perform like a conventional panel in similar conditions. However, when the sun does shine, the panel provides increased electrical output compared to a conventional panel because some fraction of the photovoltaic strips are illuminated by concentrated sunlight. In the second embodiment, however, in continuous, uninterrupted sunlight, a multiplicity of transverse portions of each photovoltaic strip are brightly illuminated and a multiplicity of transverse portions of each photovoltaic strip are poorly illuminated. As a result, the entire photovoltaic strip operates at a very low output. Only in areas with more diffuse sunlight does the output of the photovoltaic strip (and panel) equal the output of a photovoltaic strip (and panel) in the first embodiment. As a result, while the latter three embodiments are disclosed, they will not be discussed in detail.

When constructed and installed in accordance with the teachings of the first, preferred, embodiment, improved conversion efficiency and electrical output result because at any one time some longitudinal linear portion of an entire photovoltaic strip is exposed to concentrated sunlight. Since the earth rotates on its axis east to west, the linear focal zones of concentrated sunlight appear to remain motionless along each strip of photovoltaic material until the sun sets and rises the next morning whereupon the linear focal point of concentrated sunlight reappears at essentially the same location as the day before and the cycle repeats.

Solar panels constructed in accordance with the teachings of the first, preferred, embodiment are said to be “partially concentrating” because only a portion of the surface of the solar panel is exposed to concentrated sunlight. As a result, only those areas of the surface of the solar panel need have photovoltaic materials affixed. Also, because of its intrinsically high solar acceptance angle, such panels provide an essentially static area of concentrated sunlight during all times of the day. While this static area of concentrated light does move slowly north and south throughout the seasons as the Earth rotates around the sun, such a solar panel can be constructed with photovoltaic strips wide enough that some portion of each photovoltaic strip is subjected to concentrated light throughout the year. Because of this, such panels are said to be “passively tracking” in both azimuth and elevation. Also, because the monolithic array of cylindrical Fresnel lenses concentrates light on the underlying photovoltaic material only in a range between greater than 1 and 10 suns (>1 kW/m² and 10 kW/m²) the heat flux in the photovoltaic material is kept to a minimum. In most applications (with a solar flux of less than about 3 suns [3 kW/m²]) active cooling systems are thus not required. Finally, when used in a cloudy or hazy environment a solar panel constructed in accordance with the teachings of the present invention generates an electrical current equal to that generated by a solar panel with an equivalent area of the same photovoltaic material and a planar glass or plastic covering.

### DETAILED DESCRIPTION OF THE INVENTION

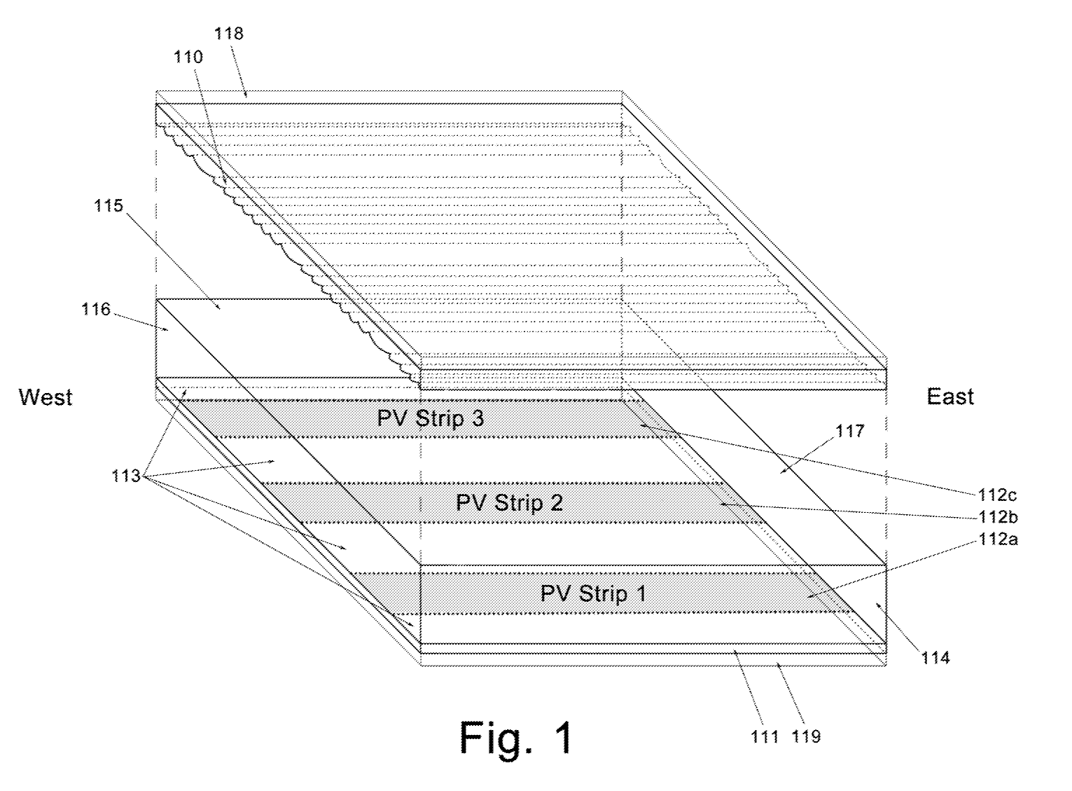

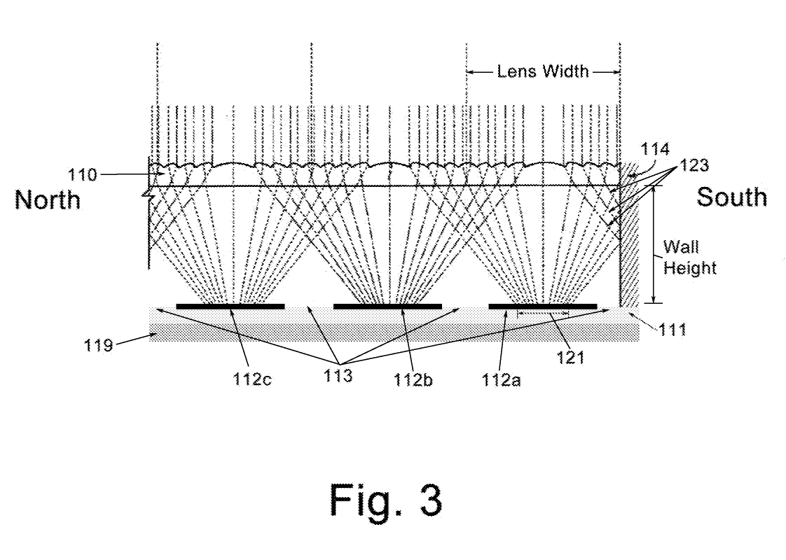

Referring now to FIGS. 1 and 3 which illustrate: 1) A partially exploded view; and, 2) A partial cross-sectional view, respectively, of a small solar panel constructed according to the teachings of the first embodiment of the present invention, a rectangular monolithic array of three linear cylindrical Fresnel lenses 110 molded or machined such that they lie edge-to-edge, is mounted atop a rectangular photovoltaic panel composed of three strips of photovoltaic material 112a, 112b, and 112c to form a passively tracking, partially concentrating solar panel. While the present example shows monolithic array of linear cylindrical Fresnel lenses 110 oriented so the linear grooves and ridges that comprise the profile of the lenses are pointed down towards strips of photovoltaic material 112a, 112b, and 112c (the “grooves down” configuration), those having skill in the art will recognize that array of linear cylindrical Fresnel lenses 110 may be oriented so the linear grooves and ridges that comprise the profile of the lenses may point up away from strips of photovoltaic material 112a, 112b, and 112c (the “grooves up” configuration). While optically equivalent, the grooves down configuration is preferred because the flat, planar surface of the monolithic array of linear cylindrical Fresnel faces up toward the environment and is easier to clean. Optionally overlying rectangular monolithic array of linear cylindrical Fresnel lenses 110 is a protective glass plate 118. Protective glass plate 118 may be coated with one or more broad-band anti-reflective substances to reduce the reflectivity of the protective glass plate and direct more of the light that impinges on the solar panel to the underlying photovoltaic panel.

Each strip of photovoltaic material 112a, 112b, and 112c is constructed of a multiplicity of unitary solar cells lying next to each other in a row and electrically connected in parallel. In other words, the positive output of one cell is wired to the positive output of its neighboring cell(s) and so on. In this preferred embodiment of the present invention, the strips of photovoltaic material 112a, 112b, and 112c are evenly spaced across the base plate 111 of the solar cell assembly with gaps 113 interposed between the strips to form a rectangular photovoltaic panel. This rectangular photovoltaic panel is supported by rectangular support structure 119. Rectangular support structure 119 may be made of any rigid or semi-rigid material capable of supporting the affixed solar panel and maintaining its planar configuration. Rectangular support structure 119 may be constructed integrally with the rest of the components of the solar panel, or, in the alternative it may be constructed separately as part of the frame to which the solar panel is mounted. In low solar flux applications—ranging between 1 sun (1 kW/m²) and 5 suns (5 kW/m²) inclusive—rectangular support structure 119 is ideally constructed of materials that feature intrinsically high thermal transmission characteristics to provide an integral passive cooling mechanism for the overlying strips of photovoltaic material 112a, 112b, and 112c. In these applications, rectangular support structure 119 may include, for example, cooling fins or projections to increase surface area and thus the ability to passively cool the overlying solar panel. For some intermediate and higher solar flux applications—above about 3 suns (3 kW/m²)—rectangular support structure 119 may include an active cooling system including without limitation: 1) Forced atmospheric air; 2) Forced gas; 3) Pumped cooling liquids; 4) Compressed refrigerant; or, 5) Fan cooled heat pipes or projections.

Supporting monolithic array of lenses 110 above base plate 111 and strips of photovoltaic material 112a, 112b, and 112c are lateral walls 114 through 117. Lateral walls 114 through 117 extend up perpendicularly from the edge of the top surface of rectangular support structure 119 and down perpendicularly from the edge of the bottom surface of array of lenses 110 and are mirrored on their inside aspects such that sunlight impinging on may be cast back into the solar panel and onto strips of photovoltaic material 112a, 112b, and 112c. For example, referring specifically to FIG. 3, sunlight 123 impinging on the northernmost face of each of the southernmost ridges of the southernmost linear cylindrical Fresnel lens comprising monolithic array of linear cylindrical Fresnel lenses 110 would ordinarily be cast onto a photovoltaic strip to the south of photovoltaic strip 112a. In this case there is no photovoltaic strip south of photovoltaic strip 112a, so sunlight 123 is reflected off of mirrored wall 114 and cast back onto photovoltaic strip 112a. Ordinarily, the focal ratio of each linear cylindrical Fresnel lens comprising monolithic array of linear cylindrical Fresnel lenses 110 is approximately f/1 and the height of lateral walls 114 through 117 is less than the focal length of each linear cylindrical Fresnel lens. When constructed in this manner the resulting solar panel comprises a sealed, hollow rectangular prism. The resulting hollow interior of the solar panel may be filled with one or more inert gases such as nitrogen or a Noble gas to prevent the condensation of water condensate.

The present invention takes advantage of the fact that, within limits, most photovoltaic material exhibits a marginally higher conversion efficiencies when exposed to concentrated sunlight. In other words, when exposed to a solar flux of 5 suns (5 kW/m²), a piece of conventional photovoltaic material generates slightly more than five times the power of an identical piece of photovoltaic material exposed to a solar flux of 1 sun (1 kW/m²). See generally, S. M. Sze and Kwok K. Ng, Physics of Semiconductor Devices, 724-725 (3d ed., John Wiley & Sons 2007). As a result, by concentrating sunlight on the underlying photovoltaic material, it is possible to both: 1) Reduce the amount of photovoltaic material necessary to construct a solar panel that generates an equivalent amount of power in direct proportion to the increase in solar flux; and, 2) Reduce the amount of photovoltaic material somewhat further still because the photovoltaic material used is operating somewhat more efficiently. However, as the amount of solar concentration increases, the thermal flux applied to the photovoltaic material increases until the conversion efficiency drops off and ultimately, the photovoltaic material is destroyed. Id. Thus, under intermediate to higher solar concentrations (above about 3 suns (3 kW/m²), it is preferable to use some type of active cooling system to prevent the thermal flux from becoming too high.

Of course, constant direct sunlight is not always available in even the sunniest locations. Conventional non-concentrating solar panels function poorly in applications where clouds are prevalent simply by virtue of the fact that comparatively less sunlight impinges on the underlying photovoltaic device. Advantageously, the present invention performs just as well as a conventional non-concentrating panel in overcast conditions. The diffuse Lambertian sunlight transiting the array of linear cylindrical Fresnel lenses emerges no less attenuated than it would have if a covering of glass or plastic was used instead. As a result, when used in a cloudy or hazy environment, a solar panel constructed in accordance with the teachings of the present invention generates an electrical current equal to a solar panel with an equivalent area of the same photovoltaic material and a planar glass or plastic covering.

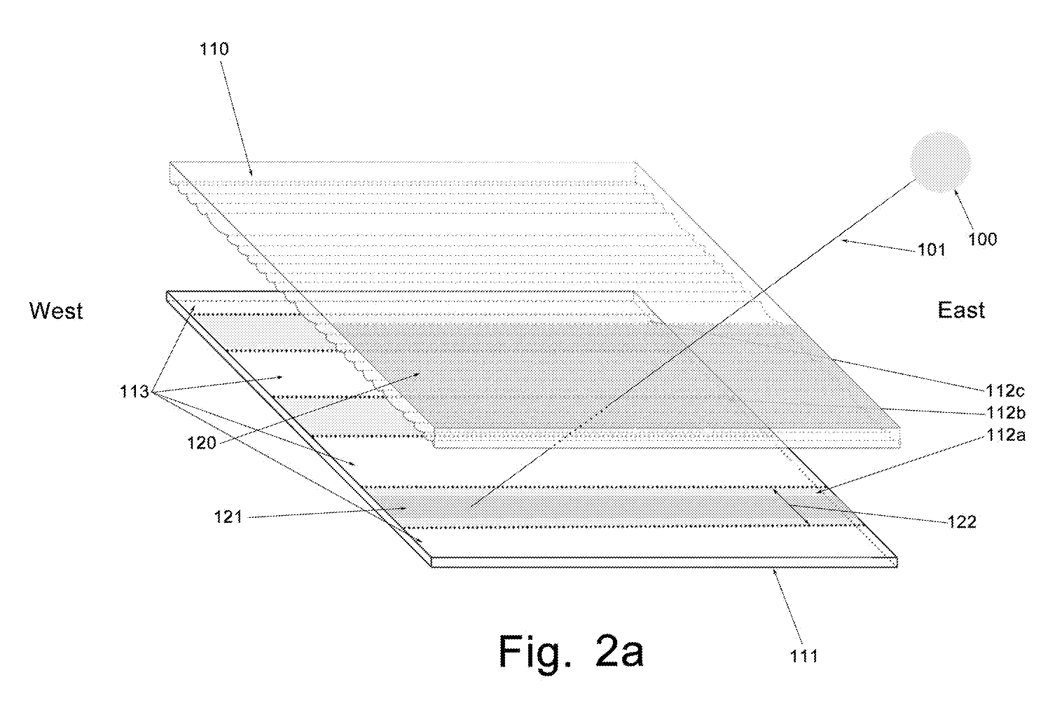

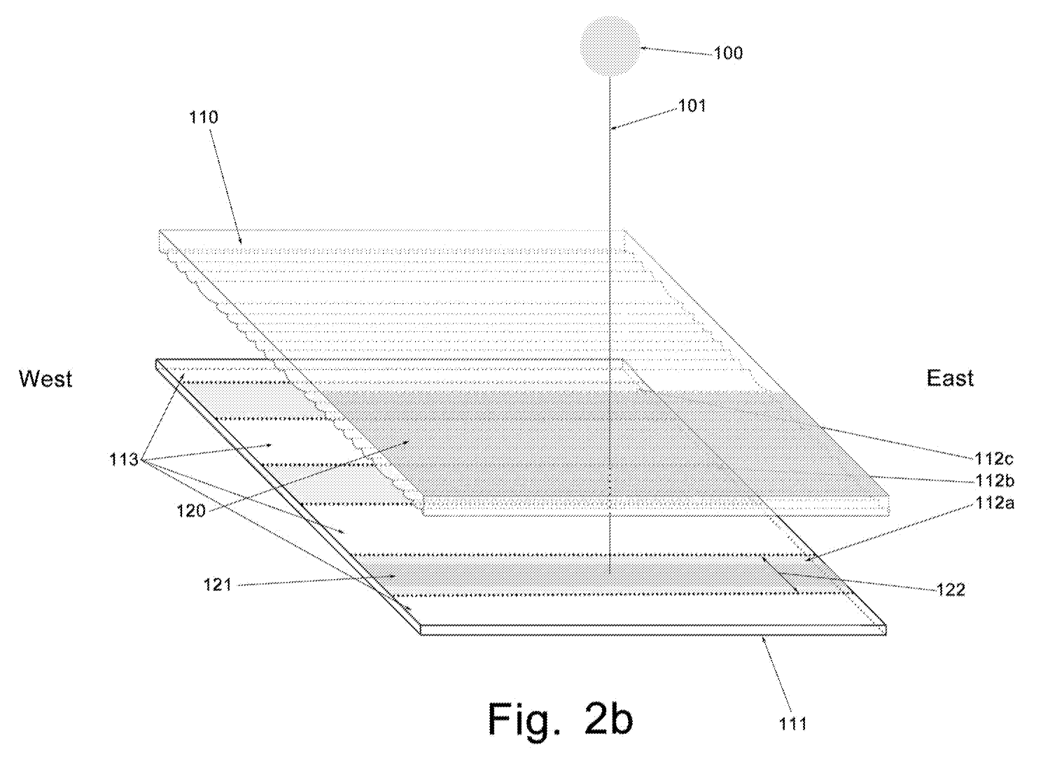

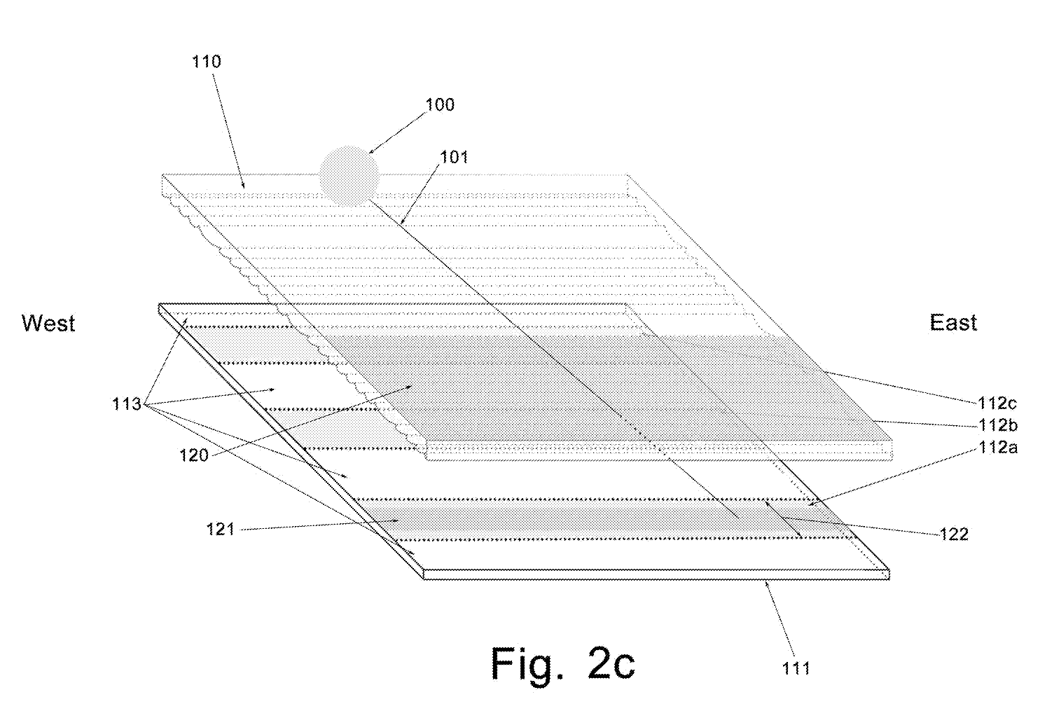

Referring now to FIGS. 2a and 3, the first, preferred, embodiment of the present invention is installed such that both the ridges and grooves that form the profile of the lens and the underlying strips of photovoltaic material 112a, 112b, and 112c are aligned east to west. Assuming that the sun 100 is at equinox (i.e. the day that it lies closest to the celestial equator) and the panel is installed at an angle such that the face of the panel points directly at the location of the sun at its zenith, sunlight 101 collected by the southernmost of the three linear cylindrical Fresnel lenses (shown as 120) that comprise array of lenses 110, falls in a linear focal zone (shown as 121) along the center longitudinal line of strip of photovoltaic material 112a. In this case, as the sun moves along the ecliptic from east to west during the day, the linear focal zone of concentrated light appears to remain motionless.

For example in FIG. 2a, sun 100 is at a position in the eastern sky in the local A.M. Sunlight 101 collected by the southernmost of the three linear cylindrical Fresnel lenses (shown as 120) that comprise monolithic array of lenses 110, falls in a linear focal zone (shown as 121) along the center longitudinal line of strip of photovoltaic material 112a.

Proceeding now to FIG. 2b, sun 100 is at a position directly overhead at its zenith or local noon. Sunlight 101 collected by the southernmost of the three linear cylindrical Fresnel lenses (shown as 120) that comprise monolithic array of lenses 110, still falls in the same linear focal zone (shown as 121) along the center longitudinal line of strip of photovoltaic material 112a as it did in the local A.M.

Proceeding now to FIG. 2c, sun 100 is at a position directly overhead in the local P.M. Sunlight 101 collected by the southernmost of the three linear cylindrical Fresnel lenses (shown as 120) that comprise monolithic array of lenses 110, still falls in the same linear focal zone (shown as 121) along the center longitudinal line of strip of photovoltaic material 112a as it did in the local A.M. and at local noon.

Referring now to FIGS. 1 and 3, those having skill in the art will recognize that the cylindrical Fresnel lenses comprising monolithic array of lenses 110 may be constructed in a variety of focal lengths and that by appropriately varying the focal length and/or the height of lateral walls 114 through 117 the linear focal line generated by a particular cylindrical Fresnel lens may appear as: 1) A sharply focused, narrow line when focused in the plane of the photovoltaic strips (not shown); 2) A less focused, wider focal zone 121 when the lens is focused behind the plane of the photovoltaic strips (shown); or, 3) A less focused, wider focal zone when the lens is focused in front of the plane of the photovoltaic strips (not shown). Also, by carefully selecting: 1) The width of each the cylindrical Fresnel lenses comprising array of lenses 110; 2) The focal length the cylindrical Fresnel lenses comprising the monolithic array of lenses 110; and, 3) The height of lateral walls 114 through 117, the area illuminated by linear focal zone of concentrated light 121 can be varied to illuminate a region of any desired width. By this means, the linear focal zone 121 generated by each one of the cylindrical Fresnel lens comprising monolithic array of lenses 110 may be adjusted to equivalently illuminate, for example, all the solar cells comprising photovoltaic strip 112a while its neighboring cylindrical Fresnel lens equivalently illuminates all the solar cells comprising photovoltaic strip 112b, and so on. In such a configuration, each solar cell in photovoltaic strips 112a, 112b, and 112c, is thus illuminated in precisely the same manner. Since the solar cells in photovoltaic strip 112a are wired in parallel (as are the solar cells in photovoltaic strips 112b and 112c) power management circuitry may be associated with: 1) Each strip; or, more advantageously, 2) The entire solar panel if all photovoltaic strips are wired in parallel to each other. The latter configuration is preferred in that it results in a significant cost savings.

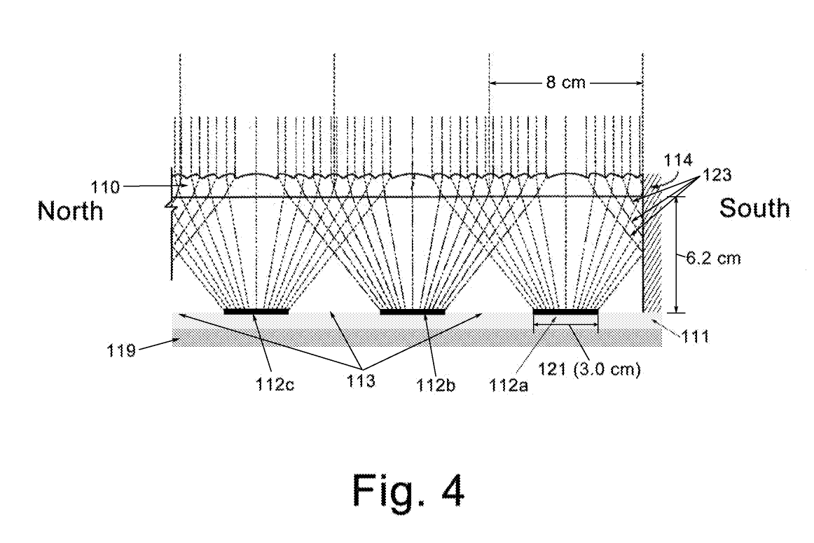

Referring now to FIGS. 1 and 4, ordinarily the height of lateral walls 114 through 117 is somewhat less than the focal length of each cylindrical Fresnel lens comprising monolithic array of lenses 110. For example, a solar panel with: 1) Each linear cylindrical Fresnel lens comprising monolithic array of lenses 110 measuring 8.0 cm in width and having a focal length of 8.0 cm; and, 2) Photovoltaic strips 112a, 112b, and 112c measuring 3.0 cm in width placed 6.2 cm directly beneath the longitudinal center line of each of linear cylindrical Fresnel lens comprising monolithic array of lenses 110, then a 3.0 cm wide focal zone 121 completely covering the respective surfaces of photovoltaic strips 112a, 112b, and 112c is evenly illuminated with a solar flux of approximately 2.6 suns (2.6 kW/m²). In this configuration, each of photovoltaic strips 112a, 112b, and 112c would be placed 5.0 cm from each other, thus leaving 5.0 cm empty zones 113 between each of photovoltaic strips 112a, 112b, and 112c.

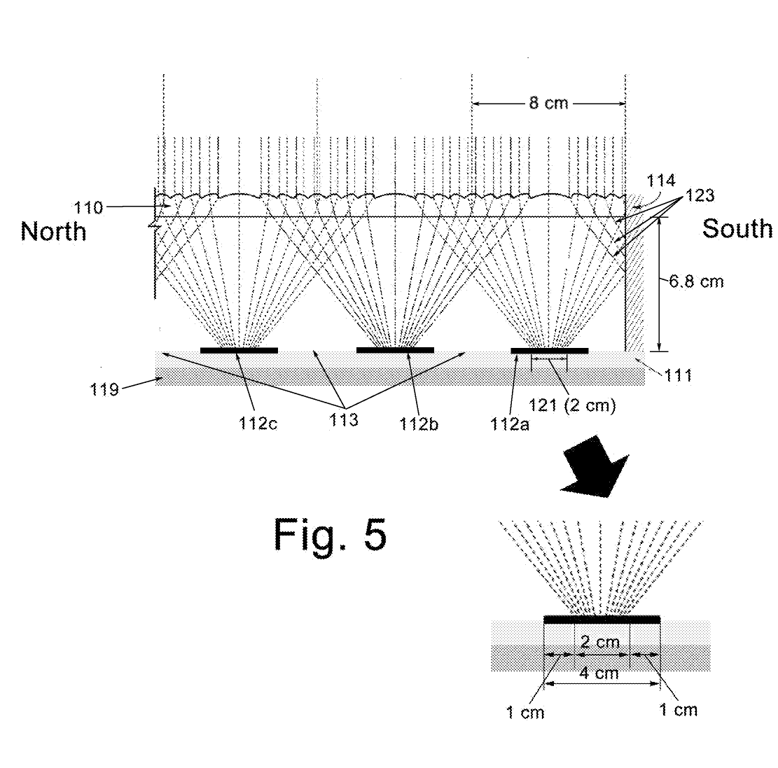

Referring now to FIGS. 1 and 5, a solar panel with: 1) Each linear cylindrical Fresnel lens comprising monolithic array of lenses 110 measuring 8.0 cm in width and each having a focal length of 8.0 cm; and, 2) Photovoltaic strips 112a, 112b, and 112c measuring 4.0 cm in width placed 6.8 cm directly beneath the longitudinal center line of each of linear cylindrical Fresnel lens comprising monolithic array of lenses 110, then a 2.0 cm wide focal zone 121 centered along the longitudinal center line of each of photovoltaic strips 112a, 112b, and 112c is illuminated with a solar flux of approximately 4.0 suns (4 kW/m²) while the remaining 1.0 cm strip on either side of focal zone 121 is subjected to Lambertian diffuse solar radiation. In this configuration, each of photovoltaic strips 112a, 112b, and 112c would be placed 4.0 cm from each other, thus leaving 4.0 cm empty zones 113 between each of photovoltaic strips 112a, 112b, and 112c.

Of course, the seasonal change in declination of the Earth's polar axis relative to the plane of the ecliptic causes the linear focal zones generated by each one of the cylindrical Fresnel lens comprising monolithic array of lenses 110 to move slowly north and south throughout the year. For example, on the equator at Quito, Ecuador the apparent elevation of the sun at its zenith can vary between approximately 68° north and 112° south with the sun appearing directly overhead twice (at the northward and southward equinoxes). Assuming, for example, a solar panel as described above in [0032], a 2.0 cm wide focal zone 121 moves approximately 2.6 cm north to 2.6 cm south of the longitudinal center line of each of photovoltaic strips 112a, 112b, and 112c during the year. Such a solar panel installed in Quito, Ecuador and pointed at the location of the sun at its zenith at the northward and southward equinoxes, focal zone 121 will be longitudinally centered on photovoltaic strip 112a throughout the day and linear focal zone 121 will be illuminated with a solar flux of approximately 4.0 suns (4 kW/m²). The remaining 1.0 cm strip on either side of focal zone 121 is subjected to Lambertian diffuse solar radiation. However, on the day of the northern solstice, the longitudinal center line of focal zone 121 will have moved 2.6 cm south of the longitudinal center line of photovoltaic strip 112a and focal zone 121 will extend off of photovoltaic strip 112a by approximately 1.6 cm. Similarly, on the day of the southern solstice, the longitudinal center line of focal zone 121 will have moved 2.6 cm north of the longitudinal center line of photovoltaic strip 112a and focal zone 121 will extend off of photovoltaic strip 112a again by approximately 1.6 cm.

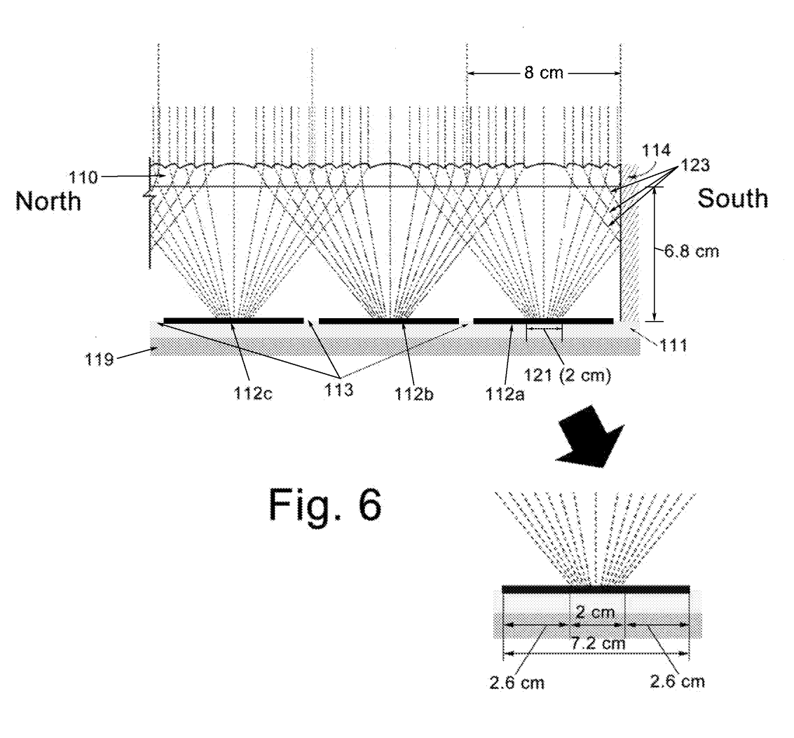

Referring now to FIG. 6, to adjust for these seasonal variations photovoltaic strip 112a may be enlarged to an optimal width of 7.2 cm (4.0 cm plus an additional 1.6 cm for the position of linear focal zone 121 at the northern solstice and 1.6 cm for the position of linear focal zone 121 at the southern solstice). A solar cell thus constructed would have three 7.2 cm wide photovoltaic strips 112a, 112b, and 112c placed such that their longitudinal center lines were directly beneath the longitudinal center lines of each respective linear cylindrical Fresnel lens comprising array of lenses 110. In this configuration, photovoltaic strips 112a, 112b, and 112c are separated by 0.8 cm empty zones 113. Assuming the following other parameters, we can thus compare the performance of a conventional solar panel with the same amount of photovoltaic material as an improved solar panel as described in this paragraph. To with:

### Conventional Solar Panel

1) Exposed to a solar flux of 1 sun (1.0 kW/m²);

2) Three 7.2 cm wide strips of polycrystalline photovoltaic material;

3) Each strip 100 cm long;

4) With a conversion ratio of 15%; and,

5) A resulting theoretical maximum output of 32.4 W.

### Improved Solar Panel

1) Exposed to a solar flux of 1 sun (1.0 kW/m²);
2) Three 7.2 cm wide strips of polycrystalline photovoltaic material (any 2.0 cm wide portion of which is exposed to a linear focal zone having a solar flux of 4.0 suns (4.0 kW/m²));
2) Each strip 100 cm long;
4) With a conversion ratio of 16% along the linear focal zone; and,
5) A resulting theoretical maximum output of 38.4 W plus any additional power generated by the 1,440 cm² of photovoltaic material exposed to diffuse Lambertian sunlight.

While both solar panels contain the same amount of photovoltaic material (2,160 cm²) the improved solar panel does not require an active tracking mechanism to keep it pointed at the sun throughout the seasons. On a constant power basis (i.e. both solar panels generating the same 38.4 W theoretical maximum output as the improved panel), a conventional solar panel requires much more photovoltaic material. Specifically, to create a conventional solar panel that generates a theoretical maximum output of 38.4 W, approximately 19% more photovoltaic material is required (˜2,550 cm² versus ˜2,160 cm²).

While the present invention is intended to be used in applications with no dynamic tracking (i.e. fixed statically pointing in one direction), those having skill in the art will recognize that by means of a single axis tracking system the amount of photovoltaic material required can be reduced dramatically. Specifically, if a single axis tracking system adjusts for variations in the sun's elevation above the horizon throughout the seasons, it is possible to create an improved solar panel with a theoretical maximum output of 38.4 W using 2.0 cm wide strips of photovoltaic material versus a conventional panel requiring 8.5 cm wide strips. Such an improved solar panel equipped with a single axis tracking system requires approximately 76% less photovoltaic material than a conventional solar panel (600 cm² versus 2,550 cm²).

As discussed above, to lower construction costs, photovoltaic strips 112a, 112b, and 112c are preferably configured with empty zones 113 lying between them. It will be evident that it is possible to install additional photovoltaic strips in these empty zones. By this means, a solar panel may be constructed with a maximal area of photovoltaic material that generates maximal power output in cloudy or overcast conditions, yet returns to its normal, higher output, partially concentrating mode of operation when the sun is bright. For example, when the sun is bright, photovoltaic strips 112a, 112b, and 112c operate in concentrating mode while the photovoltaic strips installed in empty zones 113 are exposed to Lambertian diffuse solar radiation. It will be evident that in this configuration at least two power management systems will be required: One for photovoltaic strips 112a, 112b, and 112c (if all the same size and all wired in parallel) and one for photovoltaic strips installed in empty zones 113 (if all the same size and all wired in parallel).

While, the present invention has been described in what is considered to be the most practical and useful configuration, those having skill in the art will recognize that by rearranging the various elements of the present invention, solar panels can be constructed in an almost infinite variety of sizes and thicknesses using Fresnel lens elements of different widths and focal lengths. Some of these arrangements yield exceptional efficiencies. For example, a theoretical solar panel approximately 1.0 m long, 24.0 cm wide, and 2.5 cm thick comprised of a grooves-out monolithic array of linear cylindrical Fresnel lenses each with a width of 4.0 cm and a focal length of 2.0 cm equipped with 6 strips of photovoltaic material 2.3 cm wide centered 1.7 cm below the monolithic array of linear cylindrical Fresnel lenses would focus a theoretical maximal solar flux of ˜3.9 suns (˜3.9 kW/m²) over its 6, 10 mm wide linear focal zones while functioning year-round as a passively tracking, partially concentrating solar panel. Such a panel would have ˜1380 cm² of photovoltaic material and would generate a theoretical maximum output of ˜37.4 W (plus any power generated by the additional ˜1080 cm² of photovoltaic material illuminated by diffuse Lambertian sunlight). A conventional panel with ˜1380 cm² of photovoltaic material would generate ˜20.7 W.

Moreover, while the present invention has been described in accordance with a preferred embodiment featuring a particular type of lens profile, it will be readily apparent that other lens profiles offer equivalent levels of functionality and that all such combinations of lens profiles are included in the spirit and scope of the present application. For example, U.S. Pat. No. 3,991,741 discloses a roof mount solar collector featuring an array of linear cylindrical Fresnel lenses. While this invention requires an active steering system to maintain the precise location of each focal line so that that it directly impinges on a particular solar collector throughout the day as the sun as it traverses the sky, it will be understood that when such lenses are used in conjunction with the teaching of the present invention to construct a photovoltaic panel, such a steering system is unneeded. Clearly, while not all such lens profiles and equivalent combinations are identified herein, it is intended that all such lens profiles and combinations are included within the spirit and scope of the present disclosure.

Also, while the present invention has been described in accordance with a preferred embodiment featuring a particular type of solar collector, i.e. a solar cell, it will be readily apparent that other types of solar collectors may be substituted. For example, a solar thermal panel in which the photovoltaic material is replaced by solar thermal collectors of the same size and in the same physical location as the photovoltaic collector they replace may be manufactured with minimal variation of the technologies and geometries discussed above. Such thermal collectors may comprise a multiplicity of spaced conduits connected end-to-end and filled with a conveying medium such as fluid or gas that is circulated by means of transfer system such as a pump, compressor, or other arrangement. The transfer system is used to move collected heat to an energy sink such as a thermal reservoir or to a point of application. The principle advantage of the partially concentrating panels of the present invention relative to standard fixed thermal solar collectors is that even though the same amount of thermal energy is collected by both, the partially concentrating effect of the present invention allows considerably higher temperatures to be achieved at the point of the thermal collector and consequently higher temperatures may be achieved in the conveying medium. As a result, higher temperatures in the thermal sink are achieved. This has several benefits. For example, higher temperatures in a thermal reservoir allow a greater amount of energy to be stored for later utilization when the sun is not shining. Similarly, higher temperatures at the point of utilization enable industrial processes not achievable with standard low temperature panels. Of course, even higher temperatures may be achieved when single axis or dual axis steering systems are used. Those having skill in the art will note that while not all equivalent combinations of thermal collectors or thermal sinks are identified herein, it is intended that all such thermal collectors and thermal sinks are included within the spirit and scope of the present disclosure.

What is claimed is:

1. A passively tracking partially concentrating solar panel comprising:
a. a support structure;
b. a photovoltaic panel mounted on top of said support structure, said photovoltaic panel being comprised of a multiplicity of strips of photovoltaic material arranged such that each of said strips of photovoltaic material lays parallel to each of the other strips of photovoltaic material;
i. wherein each of said strips of photovoltaic material is located a distance from each of its neighboring strips of photovoltaic material ranging from about 0 to about 4 times the width of each of said strips of photovoltaic material;
ii. wherein each of said strips of photovoltaic material is comprised of a multiplicity of discreet cells of photovoltaic material;
iii. wherein each of said multiplicity of discreet cells of photovoltaic material are electrically connected such that the positive output of each of said multiplicity of cells of photovoltaic material is connected in parallel with the positive outputs of the others and the negative output of each of said multiplicity of cells of photovoltaic material is connected in parallel with negative outputs of the others;
c. four lateral walls mounted along, and perpendicularly up, each edge of said photovoltaic panel such that each of said four lateral walls points toward, and is parallel with, the lateral wall mounted on the opposite edge of said photovoltaic panel;
i. wherein said four lateral walls are mirrored;
ii. wherein said four lateral walls range in height from about 5 mm to about 200 mm; and,
d. a rectangular planar array of linear cylindrical Fresnel lenses mounted on top of said four lateral walls such that the grooves and ridges that form the cross-sectional profile of the rectangular array of linear cylindrical Fresnel lenses lay parallel to the longitudinal center lines of said strips of photovoltaic material.

2. A passively tracking partially concentrating photovoltaic solar panel of claim 1 wherein said support structure is a solid plate.

3. A passively tracking partially concentrating photovoltaic solar panel of claim 1 wherein said support structure is a frame.

4. A passively tracking partially concentrating photovoltaic solar panel of claim 1 wherein said support structure is constructed of metal with cooling projections on its bottom aspect.

5. A passively tracking partially concentrating photovoltaic solar panel of claim 1 wherein said support structure is equipped with an active cooling system comprising a selection from a group consisting of:
a. forced atmospheric air, and
b. forced gas, and
c. pumped cooling liquid, and
d. compressed refrigerant, and
e. fan cooled heat pipes, and
f. fan cooled projections.

6. A passively tracking partially concentrating photovoltaic solar panel of claim 1 wherein the cavity formed between said rectangular array of linear cylindrical Fresnel lenses, said four lateral walls, and said photovoltaic panel is sealed to the atmosphere and filled with a gas comprising a selection from a group consisting of:
a. a Noble gas, and
b. Nitrogen, and
c. de-humidified air.

7. A passively tracking partially concentrating photovoltaic solar panel of claim 1 wherein said multiplicity of cells of photovoltaic material are monocrystalline solar cells.

8. A passively tracking partially concentrating photovoltaic solar panel of claim 1 wherein said multiplicity of cells of photovoltaic material are polycrystalline solar cells.

9. A passively tracking partially concentrating photovoltaic solar panel of claim 1 wherein said multiplicity of cells of photovoltaic material are thin film solar cells.

10. A passively tracking partially concentrating photovoltaic solar panel of claim 1 wherein the positive output and negative output of each of said strips of photovoltaic material are connected to one of a multiplicity of unitary inverters and power management systems.

11. A passively tracking partially concentrating photovoltaic solar panel of claim 1 wherein:
a. the positive output and negative output of each of said strips of photovoltaic material positioned with its longitudinal center line directly underneath the longitudinal center line of any one of the cylindrical Fresnel lens comprising said rectangular array of linear cylindrical Fresnel lenses is connected to a first inverter and power management system; and
b. the positive output and negative output of each of said strips of photovoltaic material positioned with its longitudinal center line not directly underneath the longitudinal center line of any one of the linear cylindrical Fresnel lens comprising said rectangular array of linear cylindrical Fresnel lenses is connected to a second inverter and power management system.

12. A passively tracking partially concentrating photovoltaic solar panel of claim 1 wherein said strips of photovoltaic material are electrically connected such that the positive output of each of said strips of photovoltaic material is connected in parallel with the positive outputs of the other of said strips of photovoltaic material and the negative output of each of said strips of photovoltaic material is connected in parallel with negative outputs of the other of said strips of photovoltaic material and thence all of said strips of photovoltaic material are connected to a unitary inverter and power management system.

13. A passively tracking partially concentrating photovoltaic solar panel of claim 1 wherein said rectangular array of linear cylindrical Fresnel lenses is machined plastic.

14. A passively tracking partially concentrating photovoltaic solar panel of claim 1 wherein said rectangular array of linear cylindrical Fresnel lenses is molded plastic.

15. A passively tracking partially concentrating photovoltaic solar panel of claim 1 wherein said rectangular array of linear cylindrical Fresnel lenses is molded glass.

16. A passively tracking partially concentrating photovoltaic solar panel of claim 1 wherein said rectangular array of linear cylindrical Fresnel lenses is extruded glass.

17. A passively tracking partially concentrating photovoltaic solar panel of claim 1 wherein said rectangular array of linear cylindrical Fresnel lenses is mounted with the grooves and ridges that form the cross-sectional profile of said rectangular array of linear cylindrical Fresnel lenses faces in and towards said photovoltaic panel.

18. A passively tracking partially concentrating photovoltaic solar panel of claim 1 wherein said rectangular array of linear cylindrical Fresnel lenses is mounted with the grooves and ridges that form the cross-sectional profile of said rectangular array of linear cylindrical Fresnel lenses faces out and away from said photovoltaic panel.

19. A passively tracking partially concentrating photovoltaic solar panel of claim 1 wherein said rectangular array of linear cylindrical Fresnel lenses is covered by a protective glass plate.

20. A passively tracking partially concentrating solar thermal panel comprising:
a. a support structure;
b. at least one continuous thermal collector mounted on top of said support structure, said continuous thermal collector being comprised of a multiplicity of fluidically coupled conduits arranged such that each conduit lays parallel to each of the other conduits;
i. wherein each conduit is located a distance from each adjacent conduit ranging from about 0 to about 4 times the width of said conduits;
ii. wherein said continuous thermal collector is fluidically connected to an energy sink and a transfer system and said transfer system is fluidically connected to said energy sink;
iii. wherein said continuous thermal collector, said energy sink, and said transfer system contain a conveying substance;
iv. wherein a transfer system is capable of circulating said conveying medium from said energy sink, to said continuous thermal collector, back to said energy sink;
c. four lateral walls mounted along, and perpendicularly up, each edge of said solar thermal panel such that each of said four lateral walls points toward, and is parallel with, the lateral wall mounted on the opposite edge of said solar thermal panel;
i. wherein said four lateral walls are mirrored;
ii. wherein said four lateral walls range in height from about 5 mm to about 200 mm; and,
d. a rectangular planar array of linear cylindrical Fresnel lenses mounted on top of said four lateral walls such that the grooves and ridges that form the cross-sectional profile of the rectangular array of linear cylindrical Fresnel lenses lay parallel to the longitudinal center lines of said conduits.
